(19) United States
(12) Patent Application Publication
(10) Pub. No.: US 2025/0277308 A1
(43) Pub. Date: Sep. 4, 2025

(54) APPARATUS AND METHOD FOR PROVIDING A PULSE OF A PRECURSOR

(71) Applicant: ASM IP Holding B.V., Almere (NL)

(72) Inventors: Jereld Lee Winkler, Gilbert, AZ (US); Harihara Krishnan Krishnamoorthy, Tempe, AZ (US); Eric James Shero, Phoenix, AZ (US); Eric Jen Cheng Liu, Tempe, AZ (US); Fu Tang, Gilbert, AZ (US); Petri Raisanen, Gilbert, AZ (US); Chaokai Chen, Chandler, AZ (US); Kyle Fondurulia, Phoenix, AZ (US)

(21) Appl. No.: 19/065,143

(22) Filed: Feb. 27, 2025

Related U.S. Application Data
(60) Provisional application No. 63/561,156, filed on Mar. 4, 2024.

(51) Int. Cl. C23C 16/455

(52) U.S. Cl. CPC C23C 16/45544

(57) ABSTRACT

Apparatus, systems and methods for providing a pulse of a precursor are provided. The apparatus, systems and methods as described herein can be used to, for example, rapidly pulse a precursor to a reactor and provide relatively high flow of a purge gas during a purge of the reactor.

### CROSS-REFERENCE TO RELATED APPLICATIONS

This application is a nonprovisional of, and claims priority to and the benefit of, U.S. Provisional Patent Application No. 63/561,156, filed Mar. 4, 2024 and entitled “APPARATUS AND METHOD FOR PROVIDING A PULSE OF A PRECURSOR,” which is hereby incorporated by reference herein.

### FIELD OF DISCLOSURE

The present disclosure generally relates to gas-phase reactor systems and methods of using the reactor systems. More particularly, the disclosure relates to apparatus and methods for providing a pulse of gas to a reaction chamber of a reactor system.

### BACKGROUND OF THE DISCLOSURE

Gas-phase reactors, such as chemical vapor deposition (CVD), plasma-enhanced CVD (PECVD), atomic layer deposition (ALD), plasma-enhanced ALD (PEALD), atomic layer etch (ALE) and the like can be used for a variety of applications. For example, such reactors can be used to deposit material on a substrate, etch material from a substrate surface, and/or to clean a surface of a substrate. The gas-phase reactors can be used in the manufacture of electronic devices, such as semiconductor devices, flat panel display devices, photovoltaic devices, microelectromechanical systems (MEMS), and the like.

A typical gas-phase reactor system includes one or more reactors, each reactor including one or more reaction chambers; one or more precursor and/or reactant gas sources fluidly coupled to the reaction chamber(s); one or more carrier and/or purge gas sources fluidly coupled to the reaction chamber(s); one or more gas distribution systems to deliver gases (e.g., the precursor/reactant gas(es) and/or carrier or purge gas(es)) to a surface of a substrate within a reaction chamber; and at least one exhaust source fluidly coupled to the reaction chamber(s).

In some processes carried out in reaction chambers, it may be desirable to provide a pulse of a precursor to a reaction chamber. For example, in a cyclical process, such as a cyclical CVD process or an ALD process or an ALE process, a precursor and/or reactant can be pulsed to the reaction chamber. A carrier or purge gas is often used to assist with providing a precursor during a pulse and the same gas is often used to purge the reaction chamber. Further, during a pulse of providing the precursor, a flowrate of the precursor is set to a predetermined value using a mass flow controller and a valve between a source of the precursor is switched between open and closed positions. While such configuration can work well in a variety of applications, typical configurations to provide a pulse of a precursor or reactant to a reaction chamber can limit a concentration of the precursor or reactant that can be delivered to the reaction chamber, be relatively slow, limit an overall purge flowrate, limit purge efficiency, exhibit leaking, and/or be prone to deposition on a backside of a substrate. Accordingly, improved apparatus and methods for providing a pulsed gas to a reaction chamber are desired.

Any discussion of problems and solutions involved in the related art has been included in this disclosure solely for the purposes of providing a context for the present disclosure, and should not be taken as an admission that any or all of the discussion was known at the time the invention was made.

### SUMMARY OF THE DISCLOSURE

Various embodiments of the present disclosure relate to apparatus and methods for providing a pulse of a gas (e.g., a precursor or reactant) to, for example, a reactor or a reaction chamber, to reactor systems including the apparatus, and to methods of using the apparatus and systems. The apparatus, systems and methods can be used in connection with a variety of applications, including, for example, the manufacturing of electronic devices. While the ways in which various embodiments of the present disclosure address drawbacks of prior methods and systems are discussed in more detail below, in general, various embodiments of the disclosure provide improved apparatus, systems, and methods suitable for providing a pulse of a precursor to a reaction chamber that allows for a higher concentration of the precursor, quicker pulsing on/off speeds, higher purge flowrates, quickly changing flowrates, and for varying a conductance of a pathway—e.g., between a source of the precursor and a reaction chamber. Exemplary apparatus and methods described herein can also reduce any system leakage and/or reduce unwanted backside deposition of a substrate.

In accordance with exemplary embodiments of the disclosure, an apparatus for providing a pulse of a precursor (e.g., to a reaction chamber) includes a pressure flow controller fluidly coupled to a carrier gas source, a precursor source comprising a precursor vessel, a precursor vessel inlet and a precursor vessel outlet, a carrier gas line comprising a first branch coupled to a flow bypass assembly and a second branch coupled to the precursor vessel inlet, and a precursor line coupled to the precursor vessel outlet. In accordance with aspects of these embodiments, the pressure flow controller is upstream of the precursor source. In accordance with further aspects, an outlet of the flow bypass assembly is coupled to the precursor line downstream of the precursor source. In accordance with yet further aspects, the flow bypass assembly comprises a first flow bypass line and a second flow bypass line, wherein a conductance of the first flow bypass line is lower than a conductance of the second flow bypass line. The first and/or second bypass line can include a corresponding first or second bypass metering valve and a corresponding first or second bypass shutoff valve. In accordance with yet additional aspects, the carrier gas line includes a carrier gas metering valve upstream of the precursor source and a carrier shutoff valve upstream of the precursor source. In accordance with further examples, the apparatus includes a back suction line. The back suction line can be coupled to the precursor line downstream of the precursor source and upstream of the outlet of the flow bypass assembly. The back suction line can include an orifice. In accordance with yet further examples, a conductance of the second flow bypass line is at least 5 to 10 times higher than a conductance of the first flow bypass line. The apparatus can further include a reactor inlet line coupled to the outlet of the flow bypass assembly. In accordance with exemplary aspects of these embodiments, a conductance of the reactor inlet line is greater than a conductance of the first flow bypass line. The apparatus can further include an accumulator coupled to the precursor vessel outlet. In such cases, a pressure sensor can be coupled to an interior of the accumulator. The pressure sensor can include a heated manometer. Exemplary apparatus can further include comprising a housing about the precursor vessel and a radiant heat source.

In accordance with yet additional embodiments of the disclosure, a reactor system is provided. Exemplary reactor systems include a reactor, a vacuum source coupled to the reactor, a controller, and an apparatus for providing a pulse of a precursor. The apparatus for providing a pulse of a precursor can be as described above or elsewhere herein.

In accordance with further embodiments, a method of pulsing a precursor (e.g., to a reaction chamber) is provided. Exemplary methods include providing a flow bypass assembly comprising a first flow bypass line and a second flow bypass line, wherein a conductance of the first flow bypass line is lower than a conductance of the second flow bypass line; using a pressure flow controller, providing a carrier gas to a precursor vessel containing a precursor therein and to the flow bypass assembly; and pulsing the precursor to the reaction chamber by opening a valve between the pressure flow controller and the precursor vessel and closing a valve in the second flow bypass line. Exemplary methods can further include a step of opening the valve in the second flow bypass line to purge the reaction chamber and/or other steps as set forth in more detail below.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIGS. 1 and 2 illustrate a reactor system including an apparatus in accordance with at least one embodiment of the disclosure.

FIGS. 3 and 4 illustrate a portion of a precursor source assembly in accordance with the disclosure.

FIG. 5 illustrates a heat pipe and an enclosure about the heat pipe in accordance with yet further examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to apparatus, reactor systems, and methods suitable for providing a pulse of a gas (e.g., a precursor) to, for example, a reaction chamber. The apparatus, systems and methods as described herein can be used to process substrates, such as semiconductor wafers, to form, for example, electronic devices. By way of examples, the apparatus, systems and methods described herein can be used to provide a precursor to deposit layers, etch layers, and/or clean a substrate or a reaction chamber.

In this disclosure, gas can include material that is a gas at normal temperature and pressure (NTP), a vaporized solid and/or a vaporized liquid, and can be constituted by a single gas or a mixture of gases, depending on the context. A gas other than a process gas, i.e., a gas introduced without passing through a gas distribution assembly, other gas distribution device, or the like, can be used for, e.g., sealing the reaction space, and can include a seal gas, such as a rare gas.

The term precursor can refer to a compound that participates in the chemical reaction that produces another compound. The term “reactant” can be used interchangeably with the term precursor. The term “inert gas” can refer to a gas that does not take part in a chemical reaction and/or does not become a part of a layer to an appreciable extent. Exemplary inert gases include helium and argon and any combination thereof. In some cases, molecular nitrogen and/or hydrogen can be an inert gas. A carrier and/or purge gas can be or include an inert gas.

As used herein, the term substrate may refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as GaAs, and can include one or more layers overlying or underlying the bulk material. Further, the substrate can include various topologies, such as recesses, lines, and the like formed within or on at least a portion of a layer of the substrate.

The term cyclic deposition process or cyclical deposition process can refer to the sequential introduction (e.g., pulsing) of precursor(s) (and/or reactant(s)) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component. The process can include a purge step after pulsing a reactant and/or precursor. In some cases, one or more reactants and/or precursors can be continuously provided to the reaction chamber and one or more other reactants and/or precursors can be pulsed to the reaction chamber. Similarly, a cyclical etch or clean process can include pulsing an etch or clean precursor followed by a purge step.

The term atomic layer deposition or ALD can refer to a vapor deposition process in which deposition cycles, typically a plurality of consecutive deposition cycles, are conducted in a process chamber. The term atomic layer deposition, as used herein, is meant to include processes designated by related terms, such as chemical vapor atomic layer deposition, when performed with alternating pulses of precursor(s)/reactive gas(es), and purge (e.g., inert carrier) gas(es).

Further, in this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, or the like. Further, in this disclosure, the terms including, constituted by and having can refer independently to typically or broadly comprising, comprising, consisting essentially of, or consisting of in some embodiments. In this disclosure, any defined meanings do not necessarily exclude ordinary and customary meanings in some embodiments.

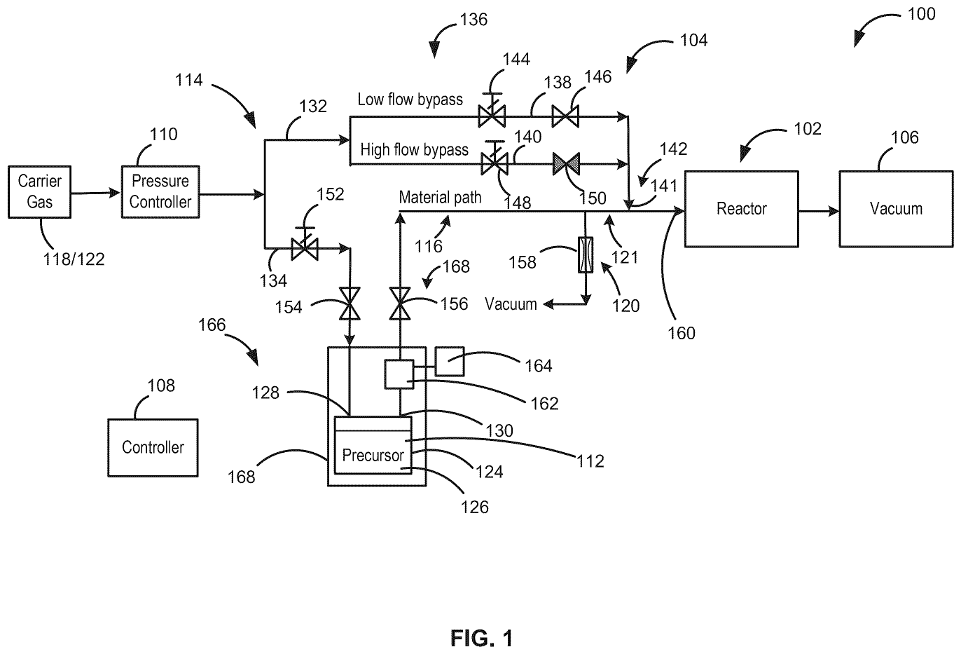

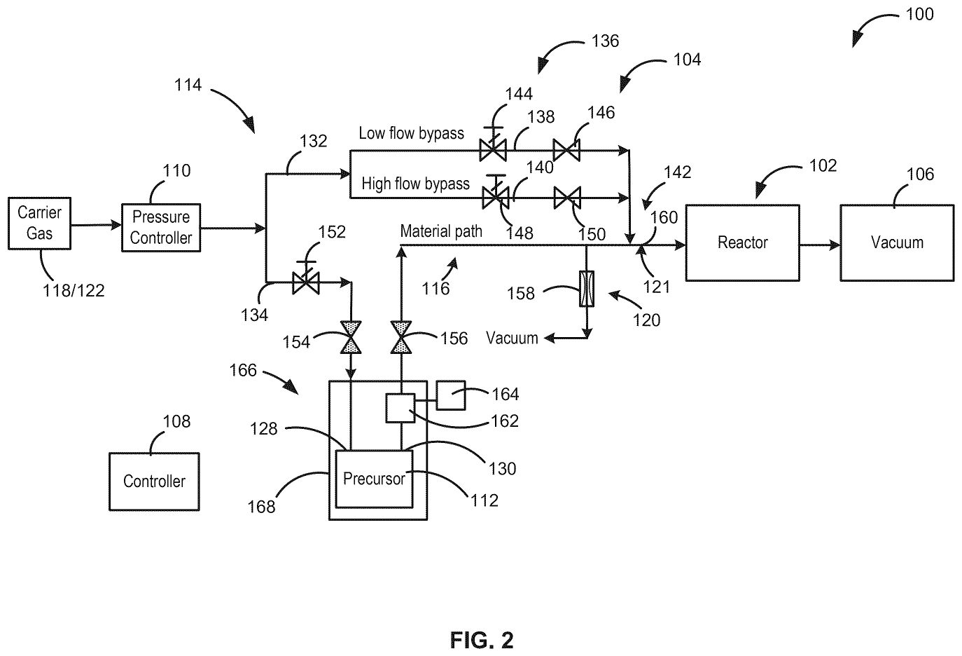

Turning now to the figures, FIGS. 1 and 2 illustrate a reactor system 100 in accordance with at least one embodiment of the disclosure. FIG. 1 illustrates system 100 in a process of providing a pulse of a precursor. FIG. 2 illustrates system 100 during a purge step of process.

Reactor system 100 includes a reactor 102, an apparatus 104 for providing a pulse of a precursor (e.g., to reactor 102), a vacuum source 106, and a controller 108. Although described herein in the context of providing a precursor, system 100 can be used to provide a pulse of any gas or volatile compound.

Reactor 102 can be or include a reaction chamber suitable for gas-phase reactions. The reaction chamber can be formed of suitable material, such as quartz, metal, or the like, and can be configured to retain one or more substrates for processing. Reactor system 100 can include any suitable number of reactors 102 and can optionally include one or more substrate handling systems.

Reactor 102 can be configured as a CVD reactor, a cyclical deposition process reactor (e.g., a cyclical CVD reactor), an ALD reactor, or the like, any of which may include plasma apparatus, such as direct and/or remote plasma apparatus. Reactor 102 can be configured to deposit a variety of films or layers, such as multi-component layers, epitaxial layers, or the like, and/or can be configured to perform an etch and/or clean process.

Apparatus 104, for providing a pulse of a precursor, includes a pressure flow controller 110, a precursor source 112, a carrier gas line 114, and a precursor line 116. In the illustrated example, apparatus 104 also includes a carrier gas source 118, a back suction line 120, and a reactor inlet line 160.

Pressure flow controller 110 can include any suitable pressure flow control device in which a pressure of a gas is controlled. By way of example, pressure flow controller 110 can be or include a pressure controller with an integral mass flow meter, such as a MKS GCPMA. Pressure flow controller 110 is fluidly coupled to (e.g., between) carrier gas source 118 and carrier gas line 114 to provide a desired amount of carrier gas to carrier gas line 114. Pressure flow controller 110 is upstream of the precursor source 112. Various lines and branches as described herein, such as carrier gas line 114, precursor line 116, bypass lines, back suction lines, and the like can be or include any suitable gas conduit, such as tubes, pipes, or the like.

Carrier gas source 118 can include a vessel 122 and a carrier gas contained therein. As noted above, exemplary carrier gases include inert gases, such as nitrogen (N₂), argon, helium, hydrogen, or the like. The carrier gas can be pressurized—e.g., to a pressure of between about 100 torr and about 900 torr. In some cases, a carrier gas can include a gas that becomes a reactant when activated by a plasma.

Precursor source 112 includes a precursor vessel 124 and a precursor 126 therein. Precursor source 112 also includes a precursor vessel inlet 128 and a precursor vessel outlet 130. Precursor line 116 and a shutoff valve 156 are fluidly coupled to a precursor vessel outlet 130.

Precursor 126 can include any suitable precursor, such as a precursor that is liquid or solid at normal pressure and temperature. By way of examples, precursor 126 can be or include one or more of a liquid or solid ALD or CVD precursor.

Carrier gas line 114 includes a first branch 132 coupled to a flow bypass assembly 136 and a second branch 134 coupled to precursor vessel inlet 128. Carrier gas line 114 can also be referred to as a purge gas line.

Flow bypass assembly 136 includes a first flow bypass line 138 and a second flow bypass line 140. In accordance with various aspects of the illustrated embodiment, a conductance of first flow bypass line 138 is lower than a conductance of the second flow bypass line 140. For example, the conductance of second flow bypass line 140 can be at least 2 to 5 times or between about 2 and about 15 times higher than the conductance of the first flow bypass line 138 or other range or value noted herein. An outlet 141 of the flow bypass assembly 136 is fluidly coupled to precursor line 116 and/or reactor inlet line 160 downstream of the precursor source 112. Reactor inlet line 160 may form part of precursor line 116 or precursor line 116 may be fluidly coupled to reactor inlet line 160. As illustrated, first flow bypass line 138 and second flow bypass line 140 are (e.g., directly) fluidly coupled to precursor line 116/reactor inlet line 160 at an area 142 that is upstream of reactor 102 and downstream of precursor source 112. Reactor inlet line 160 spans from area 142 to an inlet of reactor 102. In accordance with examples of the disclosure, a conductance of reactor inlet line 160 is greater than a conductance of first flow bypass line 138. For example, a conductance of reactor inlet line 160 can be greater than 2, greater than 5, or between about 2 to 5 or between about 2 to 15 times higher than a conductance of first flow bypass line 138.

As illustrated, first flow bypass line 138 includes a first bypass metering valve 144 and a first bypass shutoff valve 146. Similarly, second flow bypass line 140 includes a second bypass metering valve 148 and a second bypass shutoff valve 150. Carrier gas line 114 also includes a carrier gas metering valve 152 and a carrier shutoff valve 154. Carrier gas metering valve 152 and carrier shutoff valve 154 are both upstream of the precursor source 112. As illustrated, metering valves 144, 148, 152 can be upstream of the respective shutoff valves 146, 150, 154. In this configuration, carrier gas line 114, first flow bypass line 138, and second flow bypass line 140 each include metering valves, which allows for variable conductance of the respective lines. This design allows for provision of higher concentration doses of precursor 126—e.g., using relatively fast shutoff of second flow bypass line 140; faster shutoff of an inert gas valve, which forms in precursor line 116 at area 142, during a start of a purge—e.g., by opening second flow bypass line 140 valves 148, 150; higher overall purge/carrier gas flows; relatively quick change of flowrates—e.g., by using pressure flow controller 110 and changing a conductance in one or more first flow bypass line 138, second flow bypass line 140, and carrier gas line 114 using metering valves 144, 148, 152; an ability to independently optimize precursor dose concentration and purge efficiency; reduce leakage by staggering flow through system 100/apparatus 104 using pressure flow controller 110, and reduce unwanted deposition or reaction on a backside of a substrate by allowing for higher purge gas flowrates that are independent of precursor concentrations.

Back suction line 120 is fluidly coupled between precursor line 116 and vacuum source 106. More particularly, back suction line 120 is fluidly coupled to precursor line 116 downstream of the precursor source 112 and upstream of the outlet 141 of flow bypass assembly 136. This design can form an inert gas valve 121, which allows for fast switching between a pulse of providing a precursor from precursor source 112 and providing a higher flow of purge gas—e.g., to reactor 102. In the illustrated example, back suction line 120 includes an orifice 158 to restrict flow in back suction line 120.

Controller 108 is configured to cause system 100 or apparatus 104 to pulse a precursor and/or perform a purge step as described herein. Controller 108 can be suitably coupled to pressure flow controller 110, metering valves 144, 148, 152 and shutoff valves 146, 150, 154 to perform the provision and purge steps described herein. Controller 108 includes electronic circuitry and software to selectively operate pressure flow controller 110 and valves 144, 148, 152, 146, 150, 154. Controller 108 can be further configured to selectively operate other manifolds, heaters, pumps (e.g., vacuum source 106) and other components of system 100. Such circuitry and components operate to introduce precursor(s) and purge gases from the respective sources 118 and 112. Controller 108 can control timing of gas pulse sequences, temperature of the substrate and/or reaction chamber, pressure within the reaction chamber, and various other operations to provide proper operation of the system 100. Controller 108 can include control software to electrically or pneumatically independently control valves 144, 148, 152, 146, 150, 154 to independently control flow of precursors and purge gases into reactor 102. Controller 108 can include modules, such as a software and/or hardware components, e.g., a FPGA or ASIC, which perform certain tasks. A module can advantageously be configured to reside on the addressable storage medium of the control system and be configured to execute one or more processes.

Vacuum source 106 can be or include one or more vacuum pumps.

As noted above, FIG. 1 illustrates system 100 during a step of pulsing the precursor to the reaction chamber. During this step, pressure flow controller 110 provides a carrier gas from carrier gas source 118 to precursor vessel 124 containing a precursor 126 therein and to flow bypass assembly 136. Shutoff valves 154, 156, and 146 are open during the step of pulsing the precursor and shutoff valve 150 is closed. Metering valves 144, 148, and 152 are all open and may be set to predetermined values.

During a purge step, as illustrated in FIG. 2, shutoff valves 154 and/or 156 are closed and second bypass shutoff valve 150 is opened to increase an amount of purge/carrier gas provided during a purge step.

In accordance with additional examples of the disclosure, a precursor source assembly 166 includes precursor source 112 and an accumulator 162 coupled to precursor vessel outlet 130, a pressure sensor 164 coupled to an interior of accumulator 162, and shutoff valves 154, 156. Precursor source assembly 166 can include a housing 168 about precursor vessel 124 and a radiant heat source, discussed in more detail below.

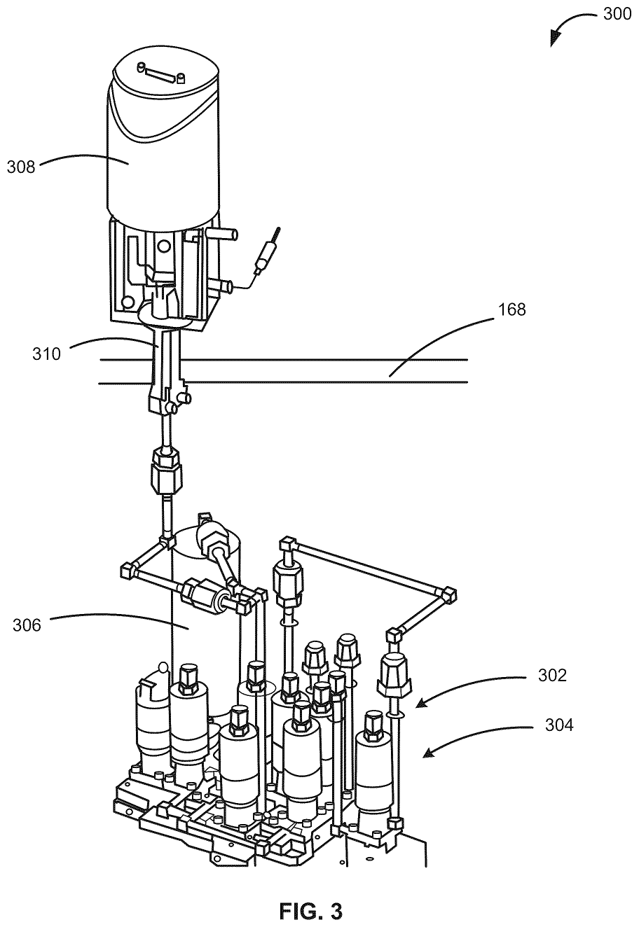

FIGS. 3-5 illustrate exemplary details of a precursor source assembly 300 suitable for use as precursor source assembly 166 in accordance with examples of the disclosure. Precursor source assembly 300 included precursor source 112 (not separately illustrated in FIGS. 3-5), a valve plate 302 comprising valves 304 coupled to vessel 124, an accumulator 306 (which can be the same as accumulator 162), and a pressure sensor 308 (which can be the same as pressure sensor 164). Pressure sensor 308 can be or include a heated manometer. Pressure sensor 308 can be used to determine an amount of material within accumulator 306. Pressure sensor 308 can be coupled to controller 108 to provide an indication of an amount of material within accumulator 306.

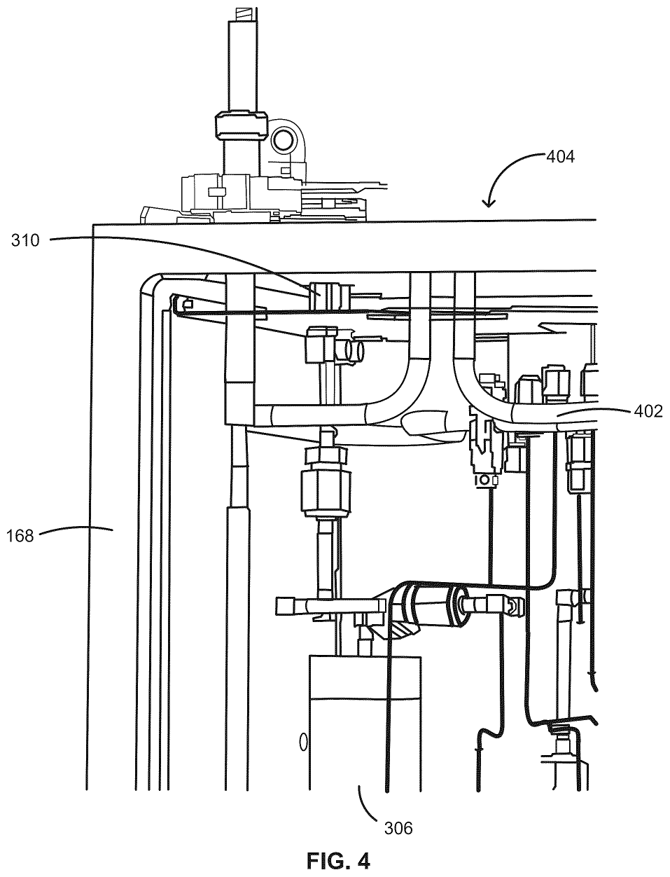

Precursor source assembly 300 also includes a radiant heat source 402, illustrated in FIG. 4, within housing 168. Radiant heat source 402 can include any suitable heat source, such as a resistive element or infrared heat source. As illustrated, radiant heat source 402 can be between accumulator 306 and pressure sensor 308. Housing 168 and radiant heat source 402 can form a heated inert gas assembly 404.

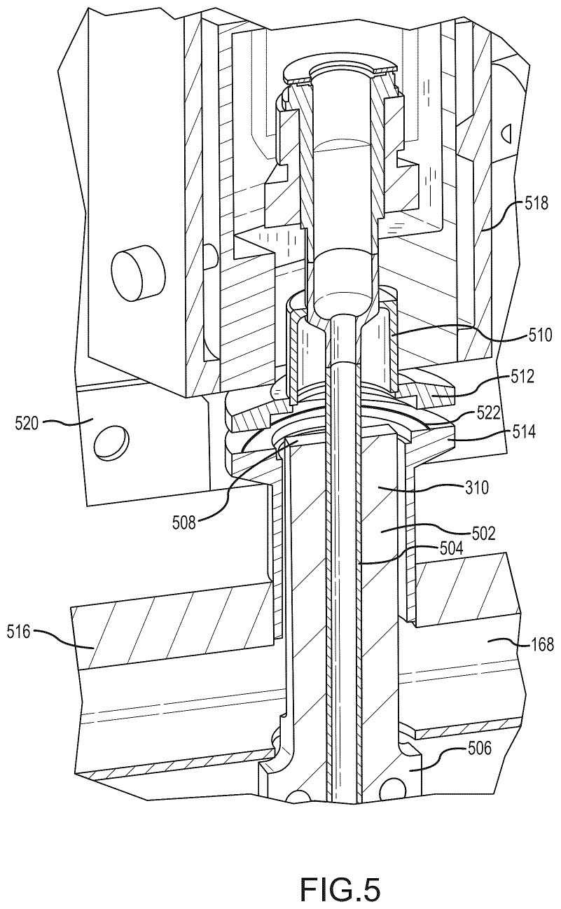

Precursor source assembly 300 also includes a heat pipe 310 to provide heat from an interior of housing 168 to pressure sensor 308. As illustrated, heat pipe 310 is interposed between accumulator 306 and the pressure sensor 308. Heat pipe 310 can be formed of any suitable heat conductive material, such as aluminum, copper, tungsten, molybdenum or thermally conductive ceramic, such as aluminum nitride. As illustrated in more detail in FIG. 5, heat pipe 310 can include two or more parts 502 that surround a tube 504 that fluidly couples accumulator 306 and pressure sensor 308. Use of two or more parts for heat pipe 310 allows for heat pipe 310 to have a relatively large bottom section or base 506, relative to a top section 508. This design allows for insertion of heat pipe 310 within a port of housing 168. Two or more parts 502 can be coupled together using any suitable technique, such as bolts, screws, adhesives, or other fasteners.

Precursor source assembly 300 also includes connector 510, which can be used to reduce heat transfer to pressure sensor 308. Connector 510 can be formed of, for example, stainless steel or the like. Connector 510 can be welded to a (e.g., KFW) seal ring or flange 512, which can be coupled to a corresponding (e.g., KFW) flange 514, which can be welded to an outer wall 516 of housing 168. A seal 522 can be interposed between flange 512 and flange 514. Seal 522 can be formed of, for example, a polymer, such as Viton, PFA, kalrez, chemrez, or the like. Precursor source assembly 300 can also include a bracket 520 about flanges 512.

Precursor source assembly 300 can also include an insulator 518 about a portion of tube 504 that is above housing 168. Insulator 518 can be formed of, for example, polyetheretherketone (PEEK) or the like.

The example embodiments of the disclosure described above do not limit the scope of the invention, since these embodiments are merely examples of the embodiments of the invention. For example, although illustrated with three gas sources, examples can include two, four, or more gas sources that may be configured in a manner similar to the illustrated examples. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. An apparatus for providing a pulse of a precursor, the apparatus comprising:
a pressure flow controller fluidly coupled to a carrier gas source;
a precursor source comprising a precursor vessel, a precursor vessel inlet and a precursor vessel outlet;
a carrier gas line comprising a first branch coupled to a flow bypass assembly and a second branch coupled to the precursor vessel inlet; and
a precursor line coupled to the precursor vessel outlet,
wherein the pressure flow controller is upstream of the precursor source, and
wherein an outlet of the flow bypass assembly is coupled to the precursor line downstream of the precursor source.

2. The apparatus of claim 1, wherein the flow bypass assembly comprises a first flow bypass line and a second flow bypass line, wherein a conductance of the first flow bypass line is lower than a conductance of the second flow bypass line.

3. The apparatus of claim 2, wherein the first flow bypass line comprises a first bypass metering valve and a first bypass shutoff valve.

4. The apparatus of claim 2, wherein the second flow bypass line comprises a second bypass metering valve and a second bypass shutoff valve.

5. The apparatus of claim 1, wherein the carrier gas line comprises a carrier gas metering valve upstream of the precursor source and a carrier shutoff valve upstream of the precursor source.

6. The apparatus of claim 1, further comprising a back suction line coupled to the precursor line downstream of the precursor source and upstream of the outlet of the flow bypass assembly.

7. The apparatus of claim 6, wherein the back suction line comprises an orifice.

8. The apparatus of claim 2, wherein a conductance of the second flow bypass line is at least 2 to 15 times higher than a conductance of the first flow bypass line.

9. The apparatus of claim 2, further comprising a reactor inlet line coupled to the outlet of the flow bypass assembly.

10. The apparatus of claim 9, wherein a conductance of the reactor inlet line is greater than a conductance of the first flow bypass line.

11. The apparatus of claim 1, further comprising an accumulator coupled to the precursor vessel outlet.

12. The apparatus of claim 11, further comprising a pressure sensor coupled to an interior of the accumulator.

13. The apparatus of claim 12, wherein the pressure sensor comprises a heated manometer.

14. The apparatus of claim 12, further comprising a heat pipe interposed between the accumulator and the pressure sensor.

15. The apparatus of claim 14, further comprising an enclosure about the heat pipe.

16. The apparatus of claim 1, further comprising a housing about the precursor vessel and a radiant heat source.

17. A reactor system comprising:
a reactor;
a vacuum source coupled to the reactor;
a controller; and
apparatus for providing a pulse of a precursor, the apparatus comprising:
a pressure flow controller fluidly coupled to a carrier gas source;
a precursor source comprising a precursor vessel, a precursor vessel inlet and a precursor vessel outlet;
a carrier gas line comprising a first branch coupled to a flow bypass assembly and a second branch coupled to the precursor vessel inlet; and
a precursor line coupled to the precursor vessel outlet,
wherein the pressure flow controller is upstream of the precursor source, and
wherein an outlet of the flow bypass assembly is coupled to the precursor line downstream of the precursor source.

18. The reactor system of claim 17, further comprising an accumulator coupled to the precursor vessel outlet and a pressure sensor coupled to the accumulator.

19. A method of pulsing a precursor to a reaction chamber, the method comprising the steps of:
providing a flow bypass assembly comprising a first flow bypass line and a second flow bypass line, wherein a conductance of the first flow bypass line is lower than a conductance of the second flow bypass line;
using a pressure flow controller, providing a carrier gas to a precursor vessel containing a precursor therein and to the flow bypass assembly; and
pulsing the precursor to the reaction chamber by:
opening a valve between the pressure flow controller and the precursor vessel; and
closing a valve in the second flow bypass line.

20. The method of claim 19, further comprising a step of opening the valve in the second flow bypass line to purge the reaction chamber.
